(19) United States
(12) Patent Application Publication
(10) Pub. No.: US 2007/0001202 A1
(43) Pub. Date: Jan. 4, 2007

(54) Structure having a dielectric layer sandwiched between two conductors for providing enhanced cracking resistance to the dielectric layer

(75) Inventors: Huai-Yuan Tseng, Pingzhen City (TW); Bo-Chu Chen, Hsinchu City (TW); Ching-Chieh Lin, Taipei City (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 11/192,179

(22) Filed: Jul. 29, 2005

(30) Foreign Application Priority Data
Jul. 1, 2005 (TW) 94122255

(51) Int. Cl. H01L 29/94; H01L 27/108; H01L 29/76; H01L 31/119

(52) U.S. Cl. 257/296

(57) ABSTRACT

A structure having a dielectric layer sandwiched between two conductors for providing enhanced cracking resistance to the dielectric layer is disclosed, which comprises a bottom electrode layer, a dielectric layer and a top electrode layer. The structure of the invention is designed with a specific layout that prevents the dielectric layer from cracking while it is formed on a flexible substrate and is subjected to a stress developed by the bending of the substrate. The structure of invention not only can enhance the reliability of an electronic component implementing the structure, but also increase the flexibility of the dielectric layer.

### FIELD OF THE INVENTION

The present invention relates to a structure having a dielectric layer sandwiched between two conductors, which is capable of providing enhanced cracking resistance to the dielectric layer while it is being formed on a flexible substrate and subjected to a stress developed by the bending of the substrate.

### BACKGROUND OF THE INVENTION

The marketplace continues to demand lighter and thinner portable electronic devices. As a result, portable electronic device manufactures require lighter, thinner flat panel displays (FPDs) for these new products. However, the development of these smaller FPDs is often at the cost of less viewing area for data display. By virtue of this, an ideal display—lighter, thinner—is a flat panel display based on a flexible substrate. The attraction of a flexible screen is obvious. Product design, for example, can form a flexible screen in a curve, enabling unheard-of form factors for cell phones shaped like a lipstick or flat TVs that fit in your pocket. Nevertheless, it is important to have every semiconductor element used in the flexible FPD to be also flexible, which is especially true for the fragile dielectric layer. That is, if the dielectric layer of a flexible FPD is cracked by the stress caused by the bending of the FPD, the phenomenon of current leakage will occur that causes the FPD to display erroneous information.

Most of the prior-art technology relating to the manufacturing of flexible FPDs are focused on either the improvement of semiconductor manufacturing process, or the materials used for making the flexible substrate and the micro-electronic components of the FPDs, i.e. a flexible substrate made of plastic or thin metal plate and micro-electronic components made of organic materials are adopted for manufacturing a flexible FPD. It is noted that there is never a technology trying to overcome the aforesaid cracking problem caused by unevenly distributed stress while bending by using a specifically designed structure and layout of the dielectric layer.

Therefore, it is in need of a structure having a dielectric layer with a specific layout sandwiched between two conductors, which is capable of providing enhanced cracking resistance to the dielectric layer while it is subjected to a stress of bending.

### SUMMARY OF THE INVENTION

In view of the disadvantages of prior art, the primary object of the present invention is provide a structure of dielectric layer for preventing the dielectric layer from cracking during flexure so as to increasing the reliability of electronic components.

It is another object of the invention to provide a structure of dielectric layer for providing enhanced flexibility to the dielectric layer

To achieve the above objects, the present invention provides a structure having a dielectric layer sandwiched between two conductors capable of providing enhanced cracking resistance to the dielectric layer while it is subjected to a stress of bending, the structure comprising: a bottom electrode layer, a dielectric layer and a top electrode layer, wherein the bottom electrode layer is formed on a flexible substrate and is consisted of a plurality of stripe-shape first bottom electrodes, each having a trapezoid cross section and being arranged parallel to a first direction; the dielectric layer is a wave-like film formed on the bottom electrode layer while covering the plural stripe-shape first bottom electrodes; and the top electrode layer is formed on the dielectric layer.

In another aspect, the present invention provides a structure having a dielectric layer sandwiched between two conductors capable of providing enhanced cracking resistance to the dielectric layer while it is subjected to a stress of bending, the structure comprising: a bottom electrode layer, a dielectric layer and a top electrode layer, wherein the bottom electrode layer is formed on a flexible substrate and is consisted of a plurality of stripe-shape first bottom electrodes and a plurality of stripe-shape second bottom electrodes, each first bottom electrode having a trapezoid cross section and being arranged parallel to a first direction while each second bottom electrode having a trapezoid cross section and being arranged parallel to a second direction, the second direction being perpendicular to the first direction; the dielectric layer is a wave-like film formed on the bottom electrode layer while covering the plural stripe-shape first and second bottom electrodes; and the top electrode layer is formed on the dielectric layer.

In another aspect, the present invention provides a structure having a dielectric layer sandwiched between two conductors capable of providing enhanced cracking resistance to the dielectric layer while it is subjected to a stress of bending, the structure comprising: a bottom electrode layer, a dielectric layer and a top electrode layer, wherein the bottom electrode layer is formed on a flexible substrate and is consisted of a plurality of stripe-shape first bottom electrodes and a plurality of stripe-shape second bottom electrodes, each first bottom electrode having a trapezoid cross section and being arranged parallel to a first direction while each second bottom electrode having a trapezoid cross section and being arranged parallel to a second direction, the formation of the plural first and second bottom electrodes enabling the bottom electrode layer to have a net-like interlacing pattern; the dielectric layer further comprises a plurality of dielectric units, neighboring dielectric units being separated from each other by a gap and each being arranged on the bottom electrode layer in accordance to the plural first and second bottom electrodes while forming a net-like pattern corresponding to that of the bottom electrode layer; the top electrode layer is consisted of a plurality of stripe-shape first top electrodes and a plurality of stripe-shape second top electrodes, each first top electrode being arranged parallel to the first direction while each second top electrode being arranged parallel to the second direction, the formation of the plural first and second top electrodes being formed on the dielectric layer while enabling the top electrode layer to have a net-like pattern corresponding to that of the dielectric layer.

It is noted that the structure of the invention is capable of preventing the dielectric layer from cracking while being bended, that is, by enabling the dielectric layer to either be a wave-like film or have a net-like interlacing pattern, the stress of flexure can be overcome and thus enhance the flexibility of the dielectric layer.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1A is a schematic diagram showing the layout of the bottom and top electrode layers according to a first embodiment of the invention.

FIG. 1B is a cross-sectional of a structure according to the first embodiment of the invention.

FIG. 2A is a schematic diagram showing the layout of the bottom and top electrode layers according to a second embodiment of the invention.

FIG. 2B is a cross-sectional of a structure according to the second embodiment of the invention.

FIG. 3A is a schematic diagram showing the layout of the bottom and top electrode layers according to a third embodiment of the invention.

FIG. 3B is a cross-sectional of a structure according to the third embodiment of the invention.

FIG. 4A s a schematic diagram showing the layout of the bottom and top electrode layers according to a fourth embodiment of the invention.

FIG. 4B is the A-A section of FIG. 4A.

FIG. 4C is a cross-sectional view of a structure according to the fourth embodiment of the invention.

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

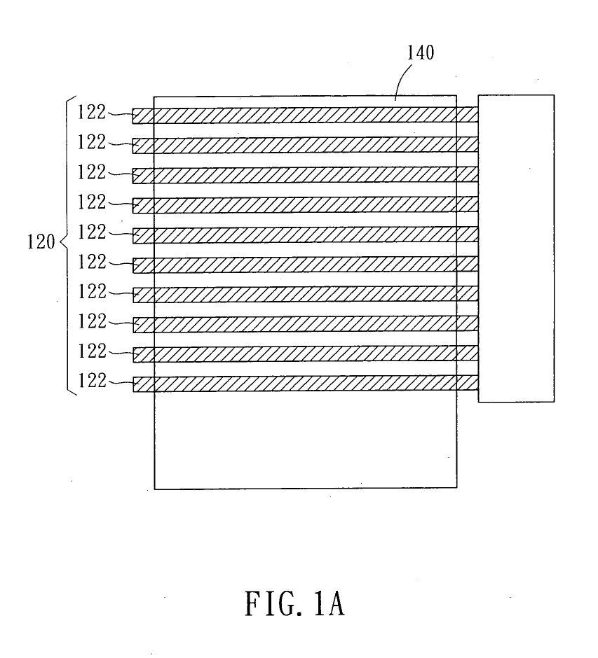

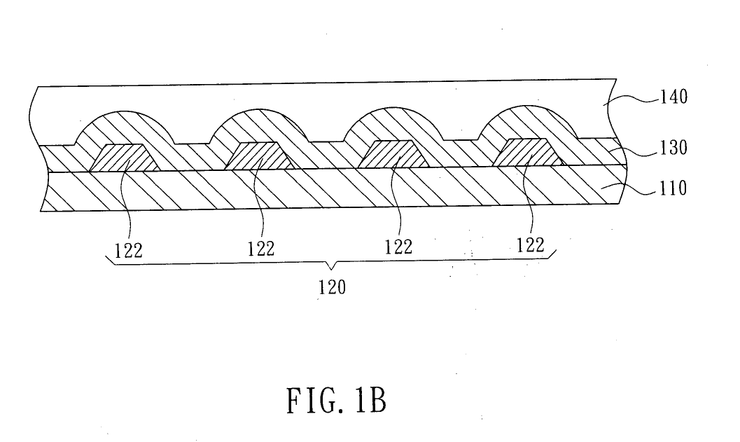

Please refer to FIG. 1A and FIG. 1B, which are schematic views of a first embodiment of the invention. In this preferred embodiment, a structure having a dielectric layer sandwiched between two conductors is disclosed, which comprises a flexible substrate 110, a bottom electrode layer 120, a dielectric layer 130 and a top electrode layer 140, wherein the bottom electrode 120 layer is formed on a flexible substrate 110 and is consisted of a plurality of stripe-shape first bottom electrodes 122, each having a trapezoid cross section and being arranged parallel to a first direction; the dielectric layer 130 is a wave-like film deposited on the bottom electrode layer 120 while covering the plural stripe-shape first bottom electrodes 122; and the top electrode layer 140 is formed on the dielectric layer 130.

Since each first bottom electrodes 122 is a stripe-like object being formed on the flexible substrate 110 parallel to the first direction, the dielectric layer 130 deposited thereon will have a wave-like appearance such that the dielectric layer 130 can have a better creaking resistance to compressive stresses and tension stresses, which are perpendicular to the first direction and are exerting thereon, while the structure is being bended. Moreover, the cross section of each first bottom electrode 122 is designed to be a trapezoid for preventing the phenomenon of stress concentration. In addition, as required by circuit design, the bottom electrode layer 120 can be connected to a power line or a ground line, and similarly that the top electrode layer 140 can be connected to a power line or a ground line. Both the top and the bottom electrode layers can be made of any suitable materials which are not specially restricted. The dielectric layer 130 can be made of either a high-k material or a low-k material.

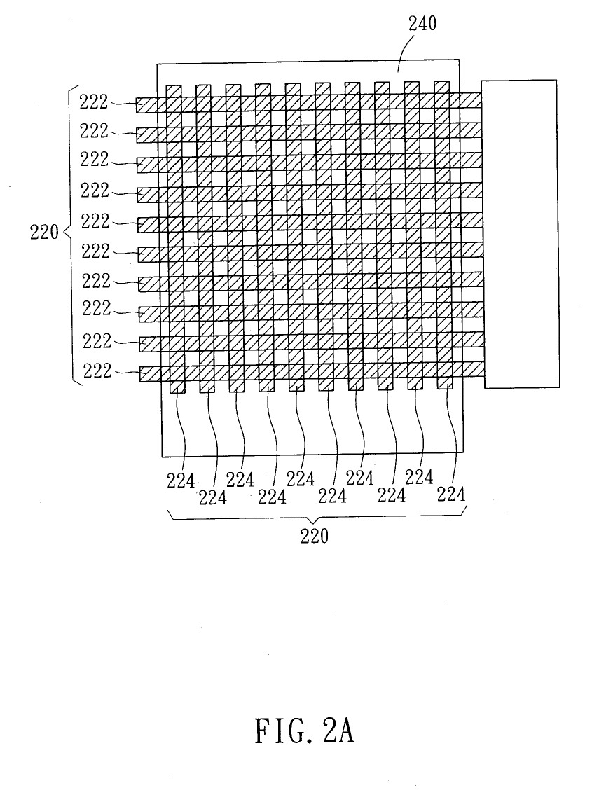

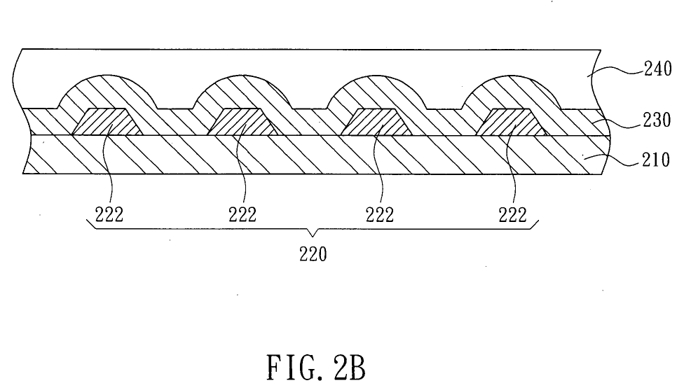

Please refer to FIG. 2A and FIG. 2B, which are schematic views of a second embodiment of the invention. In this preferred embodiment, a structure having a dielectric layer sandwiched between two conductors is disclosed, which comprises a flexible substrate 210, a bottom electrode layer 220, a dielectric layer 230 and a top electrode layer 240, wherein the bottom electrode layer 220 is formed on a flexible substrate and is consisted of a plurality of stripe-shape first bottom electrodes 222 and a plurality of stripe-shape second bottom electrodes 224, each first bottom electrode 222 having a trapezoid cross section and being arranged parallel to a first direction while each second bottom electrode 224 having a trapezoid cross section and being arranged parallel to a second direction, the second direction being perpendicular to the first direction; the dielectric layer 230 is a wave-like film deposited on the bottom electrode layer 220 while covering the plural stripe-shape first and second bottom electrodes 222, 224; and the top electrode layer 240 is formed on the dielectric layer 230.

Since the formation of the plural first and second bottom electrodes 222, 224 enables the bottom electrode layer 220 to have a net-like interlacing pattern, the dielectric layer 230 deposited thereon will be a wave-like film with interlacing pattern such that the dielectric layer 230 can have a better creaking resistance to compressive stresses and tension stresses exerting thereon, no matter they are perpendicular to the first direction or the second direction, while the structure is being bended. Moreover, the cross section of both the first bottom electrode 222 and the second bottom electrode 224 are designed to be a trapezoid for preventing the phenomenon of stress concentration. In addition, as required by circuit design, the bottom electrode layer 220 can be connected to a power line or a ground line, and similarly that the top electrode layer 240 can be connected to a power line or a ground line. Both the top and the bottom electrode layers 220, 240 can be made of any suitable materials which are not specially restricted. The dielectric layer 230 can be made of either a high-k material or a low-k material.

As seen in the first embodiment and the second embodiment of the invention, the wave-like dielectric layer is elastic and can be stretched in a way similar to a spring being pulled while it is subjected to a tension stress caused by the bending of the flexible substrate. It is noted that the conventional flat dielectric layer is more likely to crack while it is subjected to a stress, since the only way for the flat dielectric layer to react to the stress is by enabling a certain portion thereof to become thinner. Therefore, the wave-like dielectric layer has a better flexibility that can endure larger stresses without cracking.

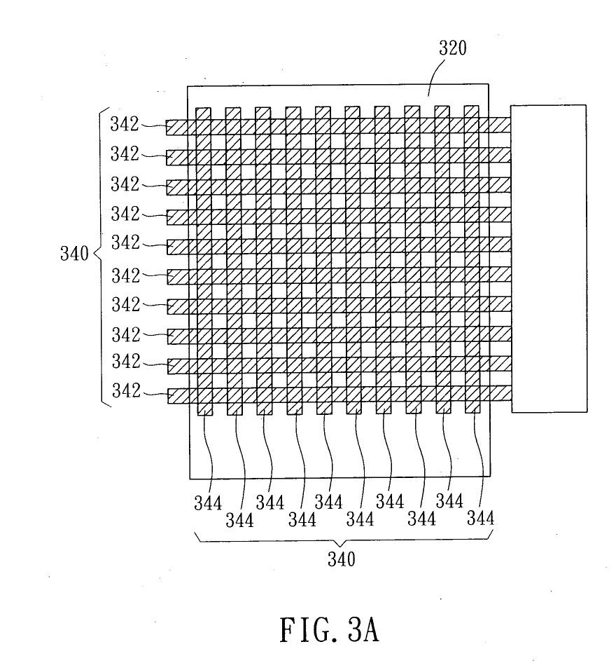

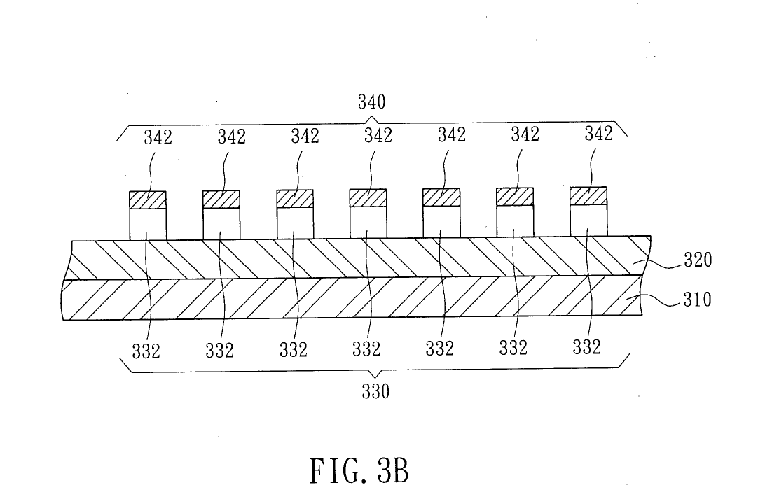

Please refer to FIG. 3A and FIG. 3B, which are schematic views of a third embodiment of the invention. In this preferred embodiment, a structure having a dielectric layer sandwiched between two conductors is disclosed, which comprises: a flexible substrate 310; a bottom electrode layer 320; a dielectric layer 330, further comprising a plurality of dielectric units 332; and a top electrode layer 340, further comprising a plurality of stripe-shape first top electrodes 342 and a plurality of stripe-shape second top electrodes 344; wherein the process of forming the plural dielectric units comprises the steps of: forming the bottom electrode layer 320 on the flexible substrate 310; forming the dielectric layer 330 on the bottom electrode layer 320; forming the plural stripe-shape first top electrodes 342 and the plural stripe-shape second top electrodes 344 on the dielectric layer 330 while the formation of the first and second top electrodes enable the top electrode layer to have a net-like interlacing pattern; etching the dielectric layer 330 at the place not covering by the interlacing pattern of the top electrode layer 340 so as to form the plural dielectric units 332 being disposed corresponding to the interlacing pattern of the first and second top electrodes 342, 344.

Since the formation of the plural dielectric units 332 enables the dielectric layer 330 to have a net-like interlacing pattern corresponding to the formation of the first and the second top electrodes 342, 344, the dielectric layer 330 can have a better creaking resistance to compressive stresses and tension stresses exerting thereon, no matter they are perpendicular to the first direction or the second direction as seen in the second embodiment of the invention, while the structure is being bended. In addition, as required by circuit design, the bottom electrode layer 320 can be connected to a power line or a ground line, and similarly that the top electrode layer 340 can be connected to a power line or a ground line. Both the top and the bottom electrode layers 320, 340 can be made of any suitable materials which are not specially restricted. The dielectric layer 330 can be made of either a high-k material or a low-k material.

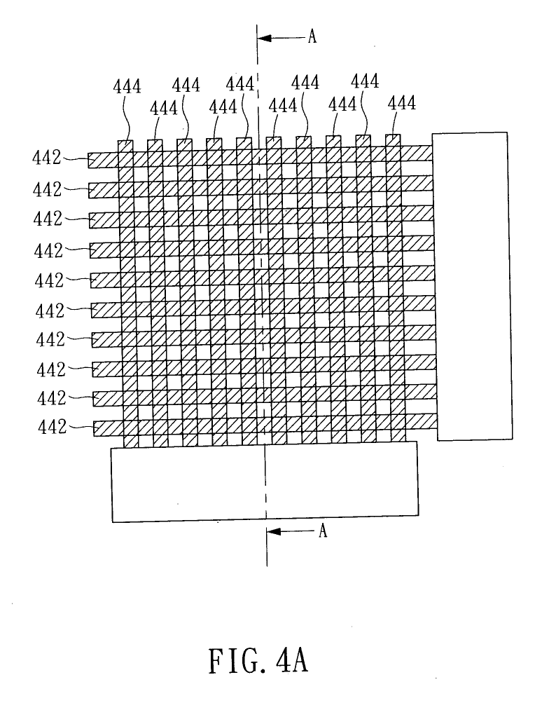

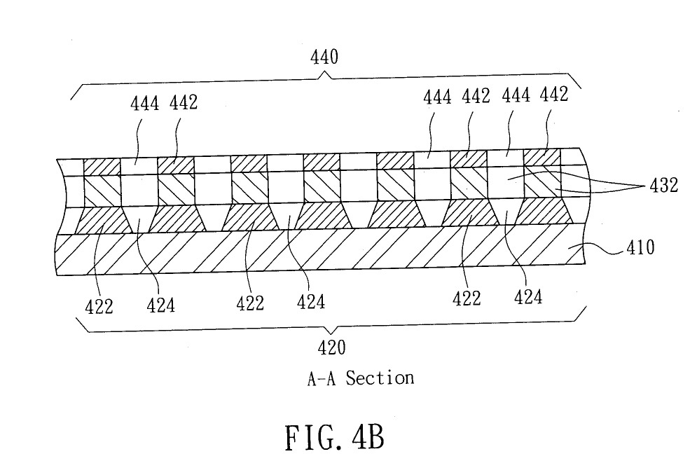

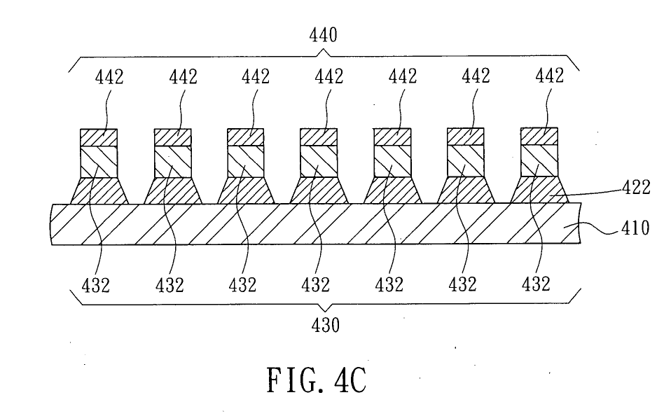

Please refer to FIG. 4A, FIG. 4B and FIG. 4C, which are schematic views of a fourth embodiment of the invention. In this preferred embodiment, a structure having a dielectric layer sandwiched between two conductors is disclosed, which comprises a flexible substrate 410, a bottom electrode layer 420, a dielectric layer 430 and a top electrode layer 440, wherein the bottom electrode layer 420 is formed on a flexible substrate 410 and is consisted of a plurality of stripe-shape first bottom electrodes 422 and a plurality of stripe-shape second bottom electrodes 424, each first bottom electrode 422 having a trapezoid cross section and being arranged parallel to a first direction while each second bottom electrode 424 having a trapezoid cross section and being arranged parallel to a second direction, the formation of the plural first and second bottom electrodes 422, 424 enabling the bottom electrode layer 420 to have a net-like interlacing pattern; the dielectric layer 430 further comprises a plurality of dielectric units 432, being arranged on the bottom electrode layer 430 in accordance to the plural first and second bottom electrodes 422, 424 while forming a net-like pattern corresponding to that of the bottom electrode layer 420; the top electrode layer 440 is consisted of a plurality of stripe-shape first top electrodes 442 and a plurality of stripe-shape second top electrodes 444, the formation of the plural first and second top electrodes 442, 444 being formed on the dielectric layer 430 while enabling the top electrode layer 440 to have a net-like pattern corresponding to that of the dielectric layer 430 formed by the plural dielectric units 432.

Since the formation of the plural dielectric units 432 enables the dielectric layer 430 to have a net-like interlacing pattern corresponding to the net-like formation of the first and the second top electrodes 442, 444 as well as the net-like formation of the first and the second bottom electrodes 422, 424, the dielectric layer 430 can have a better creaking resistance to compressive stresses and tension stresses exerting thereon, no matter they are perpendicular to the first direction or the second direction as seen in the second embodiment of the invention, while the structure is being bended. Moreover, the cross section of both the first bottom electrode 422 and the second bottom electrode 424 are designed to be a trapezoid for preventing the phenomenon of stress concentration. In addition, as required by circuit design, the bottom electrode layer 420 can be connected to a power line or a ground line, and similarly that the top electrode layer 440 can be connected to a power line or a ground line. Both the top and the bottom electrode layers 420, 440 can be made of any suitable materials which are not specially restricted. The dielectric layer 430 can be made of either a high-k material or a low-k material.

As shown in the third and the fourth embodiments, the dielectric layer with interlacing net-like pattern can provide a larger area for resisting the stress caused by the bending of the flexible substrate, since the deformation of strain is at an inverse ratio to the area subjecting the stress. Therefore, the dielectric layer with interlacing net-like pattern will have a better flexibility that can endure larger stresses without cracking.

To sum up, the present invention provides a structure having a dielectric layer sandwiched between two conductors for providing enhanced cracking resistance to the dielectric layer, which comprises a bottom electrode layer, a dielectric layer and a top electrode layer. The dielectric layer of the invention is designed to be a wave-like film or with a specific layout of interlacing net-like pattern that is capable of preventing the dielectric layer from cracking while it is formed on a flexible substrate and is subjected to a stress developed by the bending of the substrate. The structure of invention not only can enhance the reliability of an electronic component implementing the structure, but also increase the flexibility of the dielectric layer. In addition, the layout of top electrode layer can be either a fence-like pattern or a net-like pattern, and similarly, the layout of bottom electrode layer can be either a fence-like pattern or a net-like pattern.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A structure having a dielectric layer sandwiched between two conductors, comprising:
a bottom electrode layer, further comprising a plurality of stripe-shape first bottom electrodes, each being arranged parallel to a first direction;
a dielectric layer, being a wave-like film formed on the bottom electrode layer while covering the plural stripe-shape first bottom electrodes; and
a top electrode layer, formed on the dielectric layer.

2. The structure of claim 1, wherein the bottom electrode layer is formed on a flexible substrate.

3. The structure of claim 1, wherein each first bottom electrode has a trapezoid cross section.

4. A structure having a dielectric layer sandwiched between two conductors, comprising:
a bottom electrode layer, further comprising a plurality of stripe-shape first bottom electrodes and a plurality of stripe-shape second bottom electrodes, each first bottom electrode being arranged parallel to a first direction while each second bottom electrode being arranged parallel to a second direction;
a dielectric layer, being a wave-like film formed on the bottom electrode layer while covering the plural stripe-shape first and second bottom electrodes; and
a top electrode layer, formed on the dielectric layer.

5. The structure of claim 4, wherein the second direction is perpendicular to the first direction.

6. The structure of claim 4, wherein the bottom electrode layer is formed on a flexible substrate.

7. The structure of claim 4, wherein each first bottom electrode has a trapezoid cross section.

8. The structure of claim 4, wherein each second bottom electrode has a trapezoid cross section.

9. A structure having a dielectric layer sandwiched between two conductors, comprising:
a bottom electrode layer;
a dielectric layer, further comprises a plurality of dielectric units, each unit being formed on the bottom electrode layer into a net-like interlacing pattern while enabling neighboring dielectric units to be separated from each other by a gap; and
a top electrode layer, formed on the dielectric layer corresponding to the interlacing pattern formed by the plural dielectric units.

10. The structure of claim 9, wherein the bottom electrode layer is formed on a flexible substrate.

11. The structure of claim 9, wherein the bottom electrode layer further comprising a plurality of stripe-shape first bottom electrodes, each first bottom electrode being arranged parallel to a first direction.

12. The structure of claim 11, wherein a portion of the dielectric units are formed respectively on each corresponding first bottom electrode.

13. The structure of claim 11, wherein each first bottom electrode has a trapezoid cross section.

14. The structure of claim 9, wherein the bottom electrode layer further comprising a plurality of stripe-shape second bottom electrodes, each first bottom electrode being arranged parallel to a second direction.

15. The structure of claim 14, wherein a portion of the dielectric units are formed respectively on each corresponding second bottom electrode.

16. The structure of claim 14, wherein each second bottom electrode has a trapezoid cross section.

17. The structure of claim 9, wherein the top electrode layer further comprising a plurality of stripe-shape first top electrodes, each being formed on a corresponding dielectric unit.

18. The structure of claim 9, wherein the top electrode layer further comprising a plurality of stripe-shape second top electrodes, each being formed on a corresponding dielectric unit.
